(19) United States
(12) Patent Application Publication
(10) Pub. No.: US 2013/0264912 A1
(43) Pub. Date: Oct. 10, 2013

(54) METHOD OF MANUFACTURING PVDF-BASED POLYMER AND METHOD OF MANUFACTURING MULTILAYERED POLYMER ACTUATOR USING THE SAME

(71) Applicants: Samsung Electronics Co., Ltd., (US); University of Ulsan Foundation for Industry Cooper, (US)

(72) Inventors: Jong-oh KWON, Suwon-si (KR); Seung-tae CHOI, Ulsan (KR)

(73) Assignees: University of Ulsan Foundation for Industry Cooperation, Ulsan (KR); SAMSUNG ELECTRONICS CO., LTD., Suwon-si (KR)

(21) Appl. No.: 13/689,201

(22) Filed: Nov. 29, 2012

(30) Foreign Application Priority Data
Mar. 6, 2012 (KR) 10-2012-0022881

(51) Int. Cl. C09D 127/16; H01L 41/083

(52) U.S. Cl. CPC C09D 127/16; H01L 41/083
USPC 310/365; 156/246; 264/104; 264/405

(57) ABSTRACT

A method of manufacturing a polyvinylidene fluoride (PVDF)-based polymer film includes: applying a solution formed by dissolving a PVDF-based polymer in a solvent, on a first substrate; forming a PVDF-based polymer film by evaporating the solvent; bonding a support film on the PVDF-based polymer film; weakening an adhesive force between the PVDF-based polymer film and the first substrate; and separating the first substrate from the PVDF-based polymer film.

### CROSS-REFERENCE TO RELATED APPLICATIONS

This application claims the benefit of Korean Patent Application No. 10-2012-0022881, filed on Mar. 6, 2012, in the Korean Intellectual Property Office, the disclosure of which is incorporated herein in its entirety by reference.

### BACKGROUND

1. Field

The present disclosure relates to a method of manufacturing a polyvinylidene fluoride (PVDF)-based polymer and a method of manufacturing a stacked-type polymer actuators using the PVDF-based polymer.

2. Description of the Related Art

Electroactive polymers (EAP) are materials that respond mechanically to electrical stimulation. An EPA material is promising for various applications because it exhibits a far greater strain (several % to several tens of %) in response to electric stimulus than that (maximum of 0.2%) of conventional ferroelectric ceramics by several tens of times. Also, EAP may be easily manufactured in various forms, and is gaining a lot of attention because they can serve as sensors or actuators. In particular, the light-weight and flexible characteristics of EAP increase the usability of sensors or actuators as flexible electronic devices. In addition, EAP is capable of mimicking biological muscles which have high fracture toughness, large strain, high vibration damping, etc., and thus, are also referred to as artificial muscles.

EAP may be classified as an electronic EAP and an ionic EAP. Electronic EAP has a fast operation speed as force received by electrons is used under an electric field, but higher voltage is needed to drive it. Ionic EAP has a slow operation speed as deformation is generated due to movements of ions but needs a lower voltage for driving. Examples of electronic EAP actuators may include dielectric elastomer actuators and PVDF-based ferroelectric polymer actuators.

An example of electronic EAPs is a poly(vinylidene fluoride-trifluoroethylene-chlorofluoroethylene) (“P(VDF-TrFE-CFE)”), which is a relaxor ferroelectric polymer. Another example is a poly(vinylidene fluoride-trifluoroethylene-chlorotrifluoroethylene) (“P(VDF-TrFE-CTFE)”). P(VDF-TrFE-CFE) is formed of a combination of VDF, TrFE, and CFE. A thickness of an EAP layer based on a currently manufacturable PVDF is about 20 μm, and to obtain a strain of, for example, 1%, a driving voltage on the order of 600 V to 800 V is required. In order to reduce the driving voltage to a level applicable to portable electronic devices, EAP is required to have a thickness as small as about 1 μm. A stack of multiple EAP layers may be formed to obtain a desired level of power.

### SUMMARY

Provided are a method of manufacturing polyvinylidene fluoride (PVDF)-based polymers with a small thickness and a method of manufacturing stacked-type polymer actuators using the PVDF-based polymers. A polymer actuator made from the PVDF-based polymers may reduce a driving voltage.

Additional aspects will be set forth in part in the description which follows and, in part, will be apparent from the description, or may be learned by practice of the presented embodiments.

According to an aspect, a method of manufacturing a polyvinylidene fluoride (PVDF)-based polymer film, the method includes: applying a solution formed by dissolving a PVDF-based polymer in a solvent, on a substrate; forming a PVDF-based polymer film by evaporating the solvent; bonding a support film on the PVDF-based polymer film; reducing an adhesive force between the PVDF-based polymer film and the substrate; and separating the substrate from the PVDF-based polymer film.

The PVDF-based polymer may include P(VDF-TrEF-CTFE) (poly(vinylidene fluoride-trifluoroethylene-chloro trifluoro ethylene)) or P(VDF-TrFE-CFE) (poly(vinylidene fluoride-trifluoroethylene-chloro fluoro ethylene).

The solvent may be methyl isobutyl ketone (MIBK), methyl ethyl ketone (MEK), or dimethylformamide (DMF).

In the applying of the PVDF-based polymer solution on a substrate, an applicator or a bar-coater may be used.

The first substrate may be formed of a material coated with a hydrophilic material.

The first substrate may be formed of glass or polymer.

In the forming of a PVDF-based polymer film by evaporating the solvent, a gas flow may be introduced above the PVDF-based polymer solution. The gas flow enables a uniform evaporation of the solvent.

The gas may be an inert gas.

The support film may include a silicon elastomer or polydimethylsiloxane (PDMS).

The support film may be formed by coating a silicone elastomer or polydimethylsiloxane (PDMS) on a polyethylene terephthalate (PET) film.

In reducing an adhesive force between the PVDF-based polymer film and the first substrate, a moisturized environment may be provided to the substrate and the PVDF-based polymer film.

The moisturized environment may be formed by using water, distilled water, deionized water, or isopropyl alcohol (IPA).

An annealing operation may be further performed after the separating the first substrate from the PVDF-based polymer film.

An electrical poling operation may be further performed after the separating the first substrate from the PVDF-based polymer film.

According to another aspect, a method of manufacturing a stacked-type polymer actuator, the method includes: preparing a plurality of transfer films that are each formed of a polyvinylidene fluoride (PVDF)-based polymer film bonded on a support film; forming a first electrode layer, and transferring the PVDF-based polymer film from any one of the plurality of transfer films, on the first electrode layer; forming a second electrode layer on the transferred PVDF-based polymer film; and transferring the PVDF-based polymer film from another one of the plurality of transfer films, on the second electrode layer.

The preparing a plurality of transfer films may be performed according to the method described above.

According to another aspect, a stacked-type polymer actuator includes a plurality of electrode layers and a plurality of polyvinylidene fluoride (PVDF)-based polymer films, wherein the plurality of electrode layers and the plurality of PVDF-based polymer films are alternately stacked.

The stacked-type polymer actuator may further include a first electrode unit and a second electrode unit respectively formed with a certain distance therebetween, wherein the plurality of electrode layers are respectively alternately connected to the first electrode unit and the second electrode unit in an stacked order.

The plurality of PVDF-based polymer films may be manufactured according to the method described above.

### BRIEF DESCRIPTION OF THE DRAWINGS

These and/or other aspects will become apparent and more readily appreciated from the following description of the embodiments, taken in conjunction with the accompanying drawings in which:

FIG. 1 is a flowchart illustrating a method of manufacturing a polyvinylidene fluoride (PVDF)-based polymer film, according to an embodiment;

FIGS. 2A through 2G are detailed views of a method of manufacturing a PVDF-based polymer film, according to an embodiment;

FIG. 3 is a schematic perspective view of a structure of a stacked-type polymer actuator according to an embodiment;

FIG. 4 is a microscopic image of damage to an electrode layer when a solvent of a PVDF-based polymer solution permeates into the electrode layer when manufacturing a stacked-type polymer actuator;

FIGS. 5A through 5G are schematic views illustrating a method of manufacturing a stacked-type polymer actuator, according to an embodiment; and

FIG. 6 is a scanning electron microscope (SEM) image of a cross-section of a stacked-type polymer actuator manufactured according to a manufacturing method of an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

FIG. 1 is a flowchart illustrating a method of manufacturing a polyvinylidene fluoride (PVDF)-based polymer film, according to an embodiment.

According to the method of manufacturing a PVDF-based polymer film of FIG. 1, a PVDF-based polymer solution is prepared and applied on a substrate, and then a solvent thereof is evaporated to form the PVDF-based polymer film. The PVDF-based polymer film is separated from the substrate.

In operation S1, a PVDF-based polymer solution in which a PVDF-based polymer is dissolved in a solvent is prepared.

Next, in operation S2, the prepared PVDF-based polymer solution is applied on a substrate, and in operation S3, the solvent is evaporated to form the PVDF-based polymer film.

Next, a support film is applied to a surface of the PVDF-based polymer film to form a laminate of the PVDF-based polymer film and the support film, in operation S4, and an adhesive force between the PVDF-based polymer film and the substrate is adjusted in operation S5. Then the substrate is separated from the PVDF-based polymer film in operation S6. In addition, an annealing operation may be performed. Alternatively, an electrical poling operation may be further performed.

Next, in operation S8, the PVDF-based polymer film may be stacked where the prepared PVDF-based polymer film is needed, using a transferring method.

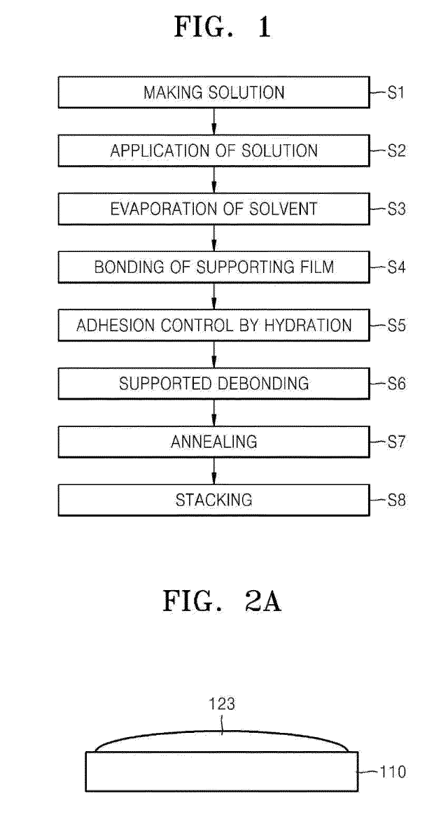

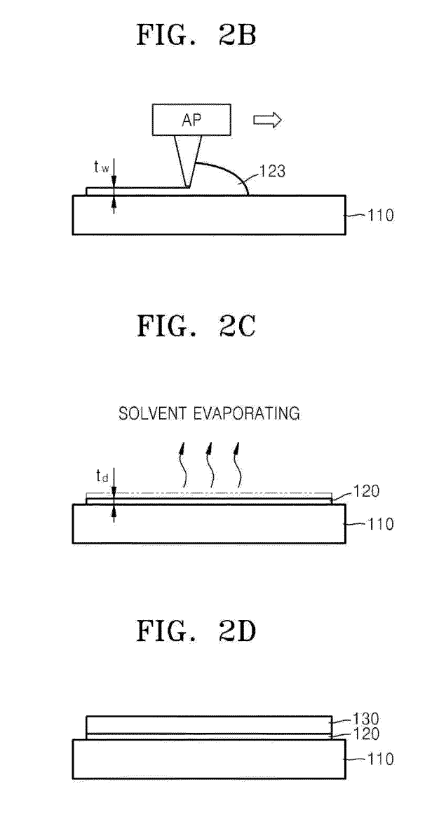

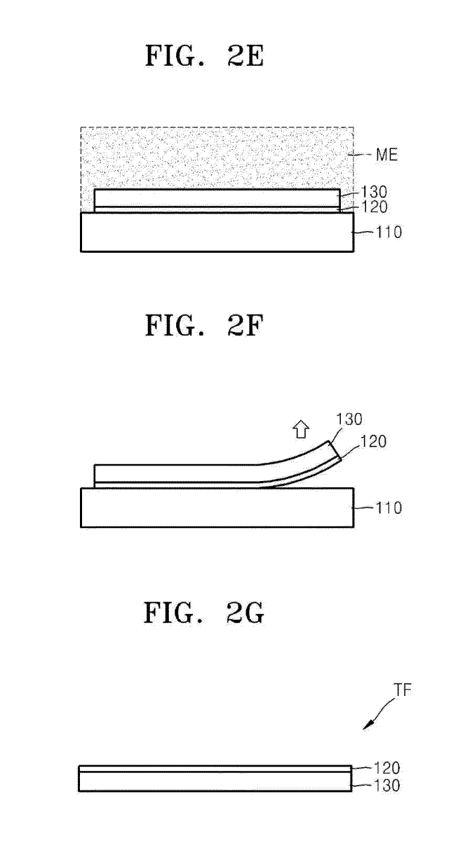

FIGS. 2A through 2G are detailed views of a method of manufacturing a PVDF-based polymer film, according to an embodiment. The method will be described in more detail with reference to FIGS. 2A through 2G.

As illustrated in FIG. 2A, a PVDF-based polymer solution 123 is applied on a first substrate 110.

The PVDF-based polymer solution 123 is formed by dissolving a PVDF-based polymer in a solvent. PVDF-based polymers are known in the art, and in an embodiment, ferroelectric polymers such as PVDF, P(VDF-TrFE), and relaxor ferroelectric polymers such as poly(vinylidene fluoride-trifluoroethylene-chlorofluoroethylene) (“P(VDF-TrFE-CFE)”), poly(vinylidene fluoride-trifluoroethylene-chlorotrifluoroethylene) (“P(VDF-TrFE-CTFE)”) may be used. Examples of the solvent may include methyl isobutyl ketone (MIBK), methyl ethyl ketone (MEK), dimethylformamide (DMF).

The first substrate 110 may have at least one hydrophilic surface, which surface will be bonded to the PVDF-based polymer. For example, the first subtrate may be a glass or polymer, which may be coated with a hydrophilic material.

Referring to FIG. 2B, an applicator AP may be used to apply the PVDF-based polymer solution 123 on the first substrate 110 with a uniform thickness tw. Also, a bar-coater may be used in coating.

Next, as illustrated in FIG. 2C, the solvent is evaporated to form the PVDF-based polymer film 120 having a thickness td. Here, a gas flow may be used above the PVDF-based polymer solution 123 to evaporate the solvent. For example, a predetermined flow of an inert gas such as N₂, O₂, or Ar may be used to uniformly evaporate the solvent. It is possible to obtain a uniform PVDF-based polymer film of a thickness of “t_{d}.”

Next, as illustrated in FIG. 2D, a support film 130 is bonded on a dried PVDF-based polymer film 120. The support film 130 may be formed of a silicone elastomer or a silicone elastomer-based polydimethylsiloxane (PDMS). Alternatively, the support film 130 may be formed of polyethylene terephthalate (PET), which is coated with a silicone elastomer or PDMS. The support film 130 may be bonded on the PVDF-based polymer film 120 using a known bonding or lamination method.

Next, referring to FIG. 2E, an adhesive force between the first substrate 110 and the PVDF-based polymer film 120 is adjusted. To weaken an interface bonding force between the first substrate 110 and the PVDF-based polymer film 120, a moisture environment (ME) may be formed. For example, by dipping the illustrated stacked structure in distilled water, water molecules may be allowed to diffuse along an interface between the first substrate 110 and the PVDF-based polymer film 120. The ME may be formed by using water, distilled water, deionized water, isopropyl alcohol (IPA), etc.

Next, referring to FIG. 2F, the support film 130 and the PVDF-based polymer film 120 may be easily separated from the first substrate 110, and accordingly, as illustrated in FIG. 2G, a transfer layer TF, which is formed of the support film 130 on which the PVDF-based polymer film 120 is bonded, is formed.

Also, in order to increase crystallinity of the PVDF-based polymer film 120, an annealing operation may be further performed. Annealing conditions such as the temperature and duration may be determined according to the desired properties of the film. For example, by optimizing a time and temperature of the annealing operation, a driving performance of the PVDF-based polymer film 120 may be improved.

In addition, an electrical poling operation for the PVDF-based polymer film 120 may be additionally performed. In the electrical poling operation, domains of dipoles that are electrically polarized are aligned in a predetermined direction by applying a high voltage to two ends of piezoelectric materials. According to the electrical poling operation, piezoelectric characteristics of the PVDF-based polymer film 120 may be improved.

According to the above-described manufacturing method, the transfer film TF including the PVDF-based polymer film 120 having a small thickness such as several micrometers, e.g., about 0.1 μm to about 5 μm, formed on the support film 130 may be manufactured, and by using the transfer film TF, the PVDF-based polymer film 120 may be easily transferred to a needed location. The PVDF-based polymer film 120 is an electronic EAP which has a higher driving voltage than that of an ionic EAP, but when manufactured to have a single micron-scale thickness according to the above-described method, a driving voltage of the electronic EAP is significantly reduced, and thus, the electronic EAP may be applied to various electronic appliances.

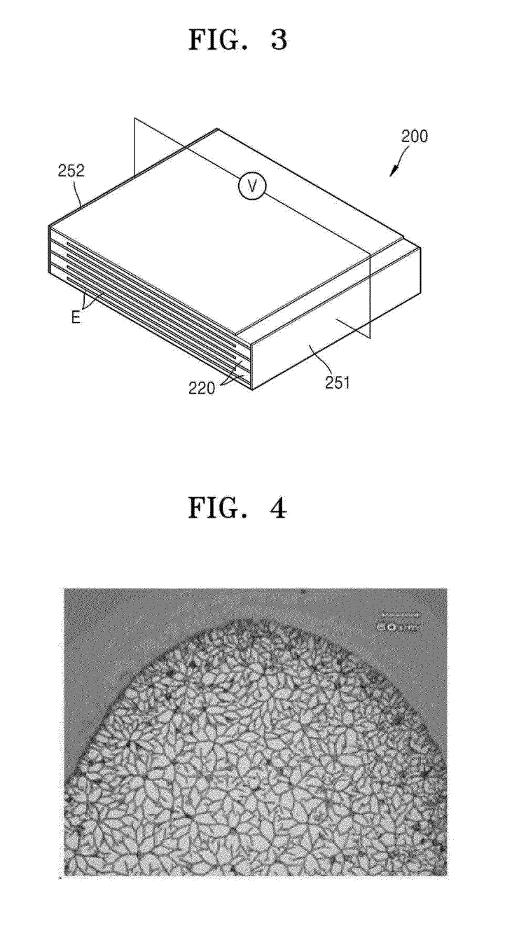

FIG. 3 is a schematic perspective view of a structure of a stacked-type polymer actuator 200 according to an embodiment. Referring to FIG. 3, the stacked-type polymer actuator 200 includes a plurality of electrode layers E and a plurality of PVDF-based polymer films 220, and has a structure in which a plurality of electrode layers E and a plurality of PVDF-based polymer films 220 are alternately stacked.

In the stacked-type polymer actuator 200, the PVDF-based polymer films 120 having a small thickness such as several um are used to reduce a driving voltage V. Also, a plurality of the PVDF-based polymer films 220 may be stacked so as to generate a desired power.

The PVDF-based polymer films 120 may be manufactured according to the method described with reference to FIGS. 2A through 2G. As different electric potential is applied to the electrode layers E disposed on and under the PVDF-based polymer films 220, the electrode layers E disposed on and under the PVDF-based polymer films 220 form an electrical field that causes deformation of the PVDF-based polymer films 220. To this end, the plurality of electrode layers E may be connected alternately to a first electrode unit 251 disposed on a right side wall and a second electrode unit 252 disposed on a left side wall, in the stacked order, as shown in FIG. 3.

When a voltage is applied between the first electrode unit 251 and the second electrode unit 252, each of the PVDF-based polymer films 220 is deformed, and a sum of deformation forces occurring in each of the plurality of PVDF-based polymer films 220 generates a driving force driving other electronic appliances.

When manufacturing the stacked-type polymer actuator having a structure as illustrated in FIG. 3, the transfer film TF formed according to the method described with reference to FIGS. 2A through 2G may be used. In a typical stacking method, damage may be caused as a solvent permeates into layers in the lower portion of the stacked-type polymer actuator 200.

FIG. 4 is a microscopic image of damage in an electrode layer when a solvent of a PVDF-based polymer solution permeates into the electrode layer when manufacturing a stacked-type polymer actuator.

A solution casting method refers to an operation in which a PVDF-based relaxor ferroelectric polymer is melted in a solvent such as methyl isobutyl ketone (MIBK) or methyl ethyl ketone (MEK) to form a PVDF-based polymer solution in a desired form, and the solvent is volatilized to a solid. In this operation, the PVDF-based polymer solution is applied using a spin coating method or an application apparatus such as an applicator. When applying the solution casting method to a stacked-type polymer structure, a solvent may permeate into layers in the lower portion of the stacked-type polymer structure when upper layers are manufactured, and thus, the lower portion of the structure may be damaged. Referring to the microscopic image of FIG. 4, P(VDF-TrFE-CTFE) having a thickness of 1 μm is formed on an aluminum electrode layer having a thickness of 20 nm, and cracks and wrinkles are generated in the aluminum electrode layer.

According to the method of manufacturing a multilayer stacked polymer actuator, according to the current embodiment of the present invention, the transfer film TF manufactured in operations described with reference to FIGS. 2A through 2G may be used to manufacture a stacked-type polymer actuator having a multi-layer structure where damage to lower layers does not occur.

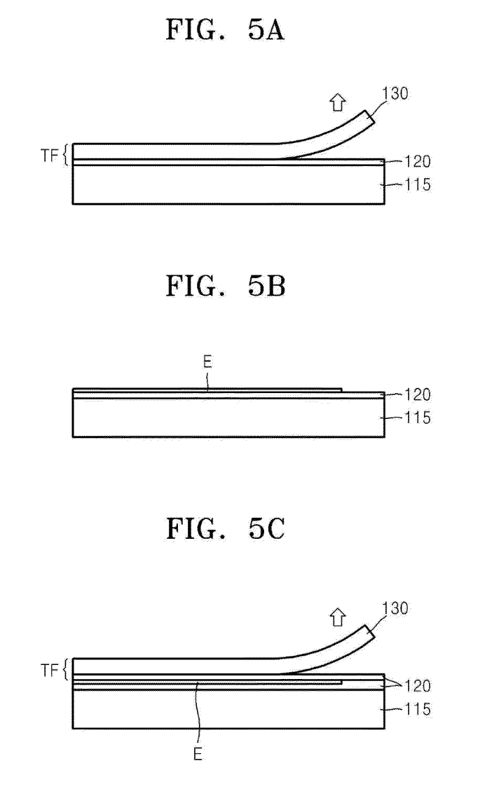

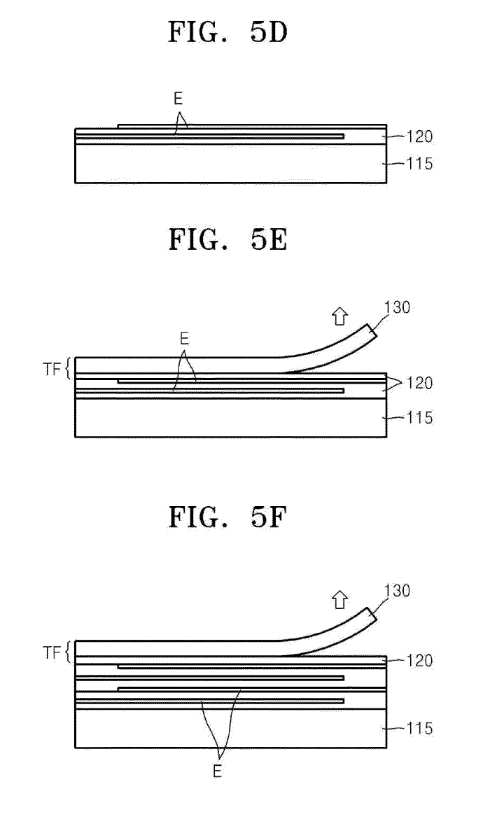

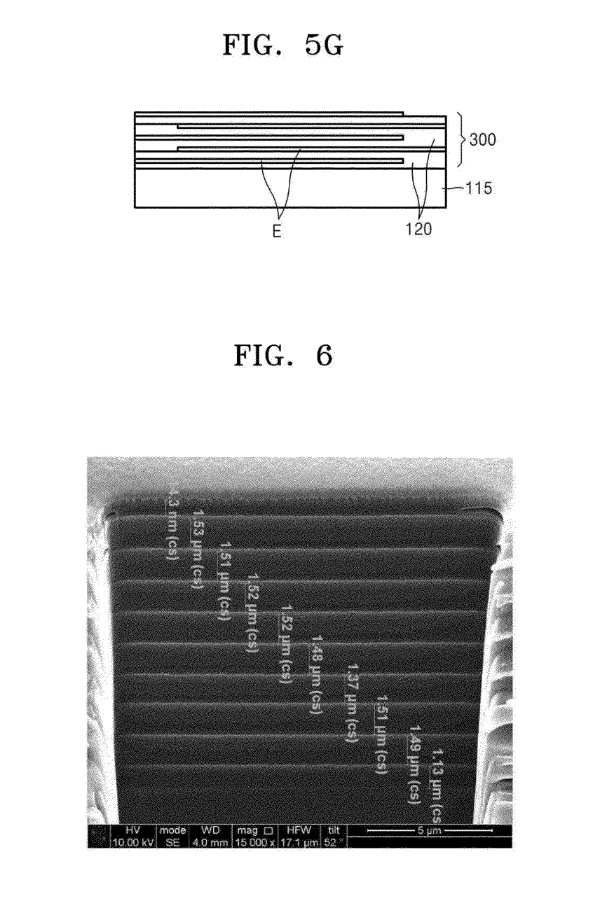

FIGS. 5A through 5G are schematic views illustrating a method of manufacturing a stacked-type polymer actuator, according to an embodiment.

FIG. 5A illustrates transferring a PVDF-based polymer film 120 on a second substrate 115. That is, a transfer film TF manufactured as illustrated in FIG. 2G is bonded on the second substrate 115, and a support film 130 is separated from the PVDF-based polymer film 120.

Next, an electrode layer E is formed on the PVDF-based polymer film 120, as illustrated in FIG. 5B.

Next, as illustrated in FIG. 5C, another transfer film TF, manufactured as illustrated in FIG. 2G, is bonded on the electrode layer E, and a support film 130 is separated from a PVDF-based polymer film 120. Then, another electrode layer E is formed on the PVDF-based polymer film 120.

In FIGS. 5E and 5F, the above-described operations are repeated in consideration of the required number of layers to be stacked, and accordingly, a stacked-type polymer actuator 300, as illustrated in FIG. 5G, is manufactured.

The second substrate 115 may be a portion of an electronic device to which the stacked polymer actuator 300 is to be applied, or the stacked polymer actuator 300 may be separated from the second substrate 115 and be disposed on a location where needed on an electronic device.

FIG. 6 is a scanning electron microscope (SEM) image of a cross-section of a stacked-type polymer actuator manufactured according to a manufacturing method of an embodiment of the present invention. Referring to FIG. 6, a P(VDF-TrFE-CTFE) film of about 1.5 μm and an aluminum electrode are alternately stacked.

According to the above-described manufacturing method, a thin PVDF-based polymer film having a thickness of about 1 um may be manufactured.

When manufacturing a stacked-type polymer actuator using a method of transferring a PVDF-based polymer film as manufactured above, damages to an electrode layer such as cracks or wrinkles may be reduced.

Also, the stacked-type polymer actuator manufactured according to the embodiments as described above has a structure in which a plurality of thin PVDF-based polymer films are stacked, and thus, a driving voltage thereof may be reduced while maintaining device performance. Thus, the stacked-type polymer actuator may be used in portable electronic devices for various purposes.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A method of manufacturing a polyvinylidene fluoride (PVDF)-based polymer film, the method comprising:
providing a solution of PVDF-based polymer in a solvent;
applying the PVDF-based polymer solution on a surface of a substrate;
evaporating the solvent to form a PVDF-based polymer film on the substrate;
applying a support film on a surface of the PVDF-based polymer film, in the order of supporting film, PVDF-based polymer film, and the substrate; and
removing the substrate from the PVDF-based polymer film.

2. The method of claim 1, wherein the separation of the first substrate from the PVDF-based polymer film comprises
weakening the adhesion between the PVDF-based polymer film and the first substrate.

3. The method of claim 1, wherein the PVDF-based polymer comprises a poly(vinylidene-fluoridetrifluoroethylene-chlorotrifluoroethylene) or poly(vinylidene fluoride-trifluoroethylene-chlorofluoroethylene).

4. The method of claim 1, wherein the solvent is methyl isobutyl ketone, methyl ethyl ketone, or dimethylformamide.

5. The method of claim 1, wherein the PVDF-based polymer film has a thickness of from about 0.1 μm to about 5 μm.

6. The method of claim 1, wherein the first substrate has at least one hydrophilic surface, said hydrophilic surface is applied with the PVDF-based polymer solution.

7. The method of claim 6, wherein the first substrate is formed of glass or a polymer, and its surface where the PVDF-based polymer solution is applied is coated with a hydrophilic material.

8. The method of claim 1, wherein the evaporation of the solvent comprises applying a gas flow above the PVDF-based polymer solution.

9. The method of claim 8, wherein the gas is an inert gas.

10. The method of claim 1, wherein the support film comprises a silicon elastomer or polydimethylsiloxane.

11. The method of claim 9, wherein the support film is formed of a polyethylene film coated with a silicone elastomer or polydimethylsiloxane.

12. The method of claim 1, wherein the separation of the substrate from the PVDF-based polymer film comprises
providing a moisture environment to the substrate and the PVDF-based polymer film.

13. The method of claim 12, wherein the moisture environment is formed by supplying water, distilled water, deionized water, or isopropyl alcohol.

14. The method of claim 1, which further comprises annealing the PVDF-based polymer film, after the substrate is separated from the PVDF-based polymer film.

15. The method of claim 1, which further comprises electrically poling the PVDF-based polymer film, after the substrate is separated from the PVDF-based polymer film.

16. A method of manufacturing a multilayer stacked polymer actuator, the method comprising:
providing a plurality of transfer films, each transfer film comprising a polyvinylidene fluoride (PVDF)-based polymer film and a support film, wherein the PVDF-based polymer film is placed on a surface of the support film;
forming a first electrode layer, and transferring a first PVDF-based polymer film from any one of the plurality of transfer films, on a surface of the first electrode layer;
forming a second electrode layer on the transferred first PVDF-based polymer film to form a stack of the second electrode, the first PVDF-based polymer film, and the first electrode, in this order; and
transferring a second PVDF-based polymer film from another one of the plurality of transfer films, on the second electrode layer to form a stack of the second PVDF-based polymer film, the second electrode, the first PVDF-based polymer film, and the first electrode, in this order.

17. The method of claim 16, wherein the providing a plurality of transfer films is performed by a process comprising:
providing a solution of PVDF-based polymer in a solvent;
applying the PVDF-based polymer solution on a surface of a substrate;
evaporating the solvent to form a PVDF-based polymer film on the substrate;
applying a support film on a surface of the PVDF-based polymer film, in the order of supporting film, PVDF-based polymer film, and the substrate; and
removing the substrate from the PVDF-based polymer film.

18. A multilayer stacked polymer actuator comprising a plurality of electrode layers and a plurality of polyvinylidene fluoride (PVDF)-based polymer films, wherein the plurality of electrode layers and the plurality of PVDF-based polymer films are alternately stacked.

19. The multilayer stacked polymer actuator of claim 18, further comprising a first electrode unit and a second electrode unit, each being separated with a certain distance,
wherein the plurality of electrode layers are respectively alternately connected to the first electrode unit and the second electrode unit in a stacked order.

20. The multilayer stacked polymer actuator of claim 18, wherein the plurality of PVDF-based polymer films are manufactured by a process comprising:
providing a solution of PVDF-based polymer in a solvent;
applying the PVDF-based polymer solution on a surface of a substrate;
evaporating the solvent to form a PVDF-based polymer film on the substrate;
applying a support film on a surface of the PVDF-based polymer film, in the order of supporting film, PVDF-based polymer film, and the substrate; and
removing the substrate from the PVDF-based polymer film.
